(19) United States
(12) Patent Application Publication
(10) Pub. No.: US 2024/0191391 A1
(43) Pub. Date: Jun. 13, 2024

(54) SEMICONDUCTOR SUBSTRATE, MANUFACTURING METHOD AND MANUFACTURING APPARATUS THEREFOR, GaN-BASED CRYSTAL BODY, SEMICONDUCTOR DEVICE, AND ELECTRONIC DEVICE

(71) Applicant: KYOCERA Corporation, Kyoto-shi, Kyoto (JP)

(72) Inventors: Toshihiro KOBAYASHI, Kyoto-shi (JP); Takeshi KAMIKAWA, Kyoto-shi (JP); Yuta AOKI, Kyoto-shi (JP); Yuichiro HAYASHI, Kyoto-shi (JP)

(73) Assignee: KYOCERA Corporation, Kyoto-shi, Kyoto (JP)

(21) Appl. No.: 18/555,197

(22) PCT Filed: Mar. 30, 2022
(86) PCT No.: PCT/JP2022/016009

§ 371 Date: Oct. 12, 2023

(30) Foreign Application Priority Data
Apr. 16, 2021 (JP) 2021-069969

(51) Int. Cl. C30B 25/04; C30B 29/38; C30B 29/40; H01L 21/02; H01L 33/20

(52) U.S. Cl. CPC C30B 25/04; C30B 29/38; C30B 29/406; H01L 21/0237; H01L 21/0254; H01L 21/02639; H01L 21/02647; H01L 33/20

(57) ABSTRACT

A semiconductor substrate includes a main substrate, a mask pattern located above the main substrate and including a mask portion, and a first semiconductor part and a second semiconductor part located above the mask pattern and adjacent to each other, in which the first semiconductor part includes a first lower edge located on the mask portion and a first protruding portion protruding toward the second semiconductor part side farther than the first lower edge.

### TECHNICAL FIELD

The present invention relates to a semiconductor substrate and the like.

### BACKGROUND OF INVENTION

For example, Patent Document 1 discloses a method of forming a plurality of semiconductor layers, each of which corresponds to a corresponding one of a plurality of opening portions of a mask, by using an epitaxial lateral overgrowth (ELO) method.

### CITATION LIST

### Patent Literature

Patent Document 1: JP 2011-66390 A

### SUMMARY

A semiconductor substrate according to the present disclosure includes a main substrate, a mask pattern located above the main substrate and including a mask portion, and a first semiconductor part and a second semiconductor part located above (in a layer above) the mask pattern and adjacent to each other, wherein the first semiconductor part includes a first lower edge located on the mask portion, and a first protruding portion protruding farther toward the second semiconductor part side than the first lower edge.

### BRIEF DESCRIPTION OF THE DRAWINGS

FIG. 1 includes a plan view and a cross-sectional view illustrating a configuration of a semiconductor substrate according to the present embodiment.

FIG. 2 is a cross-sectional view illustrating another configuration of the semiconductor substrate according to the present embodiment.

FIG. 3 is a flowchart illustrating an example of a manufacturing method for manufacturing the semiconductor substrate according to the present embodiment.

FIG. 4 is a block diagram illustrating an example of a manufacturing apparatus for manufacturing the semiconductor substrate according to the present embodiment.

FIG. 5 is a flowchart illustrating an example of a manufacturing method for manufacturing a semiconductor device according to the present embodiment.

FIG. 6 is a plan view illustrating an example of isolation of an element portion.

FIG. 7 is a cross-sectional view illustrating an example of isolation and separation of the element portion.

FIG. 8 is a schematic view illustrating a configuration of an electronic device according to the present embodiment.

FIG. 9 is a schematic view illustrating another configuration of the electronic device according to the present embodiment.

FIG. 10 is a plan view and a cross-sectional view illustrating a configuration of a semiconductor substrate according to Example 1.

FIG. 11 is a cross-sectional view illustrating an example of lateral growth of an ELO semiconductor layer.

FIG. 12 is a cross-sectional view illustrating another configuration of the semiconductor substrate according to Example 1.

FIG. 13 is a cross-sectional view illustrating another configuration of the semiconductor substrate according to the present embodiment.

FIG. 14 is a plan view illustrating a step of isolating an element portion in Example 1.

FIG. 15 is a cross-sectional view illustrating a step of separating the element portion in Example 1.

FIG. 16 is a cross-sectional view illustrating another configuration of the semiconductor substrate of Example 1.

FIG. 17 is a cross-sectional view illustrating another configuration of the semiconductor substrate 10 of Example 1.

FIG. 18 is a cross-sectional view illustrating another example of separation of the element portion.

FIG. 19 is a cross-sectional view illustrating a configuration of the semiconductor substrate of Example 2.

FIG. 20 is a cross-sectional view illustrating another configuration of the semiconductor substrate according to Example 2.

FIG. 21 is a cross-sectional view illustrating another configuration of the semiconductor substrate of Example 2.

FIG. 22 is a cross-sectional view illustrating another configuration of the semiconductor substrate of Example 2.

FIG. 23 is a schematic cross-sectional view illustrating a configuration of Example 4.

FIG. 24 is a cross-sectional view illustrating an example of application of Example 4 to an electronic device.

FIG. 25 is a schematic cross-sectional view illustrating a configuration of Example 5.

FIG. 26 is a cross-sectional view illustrating a configuration of Example 6.

FIG. 27 is a cross-sectional view illustrating a configuration of Example 7.

### DESCRIPTION OF EMBODIMENTS

### Semiconductor Substrate

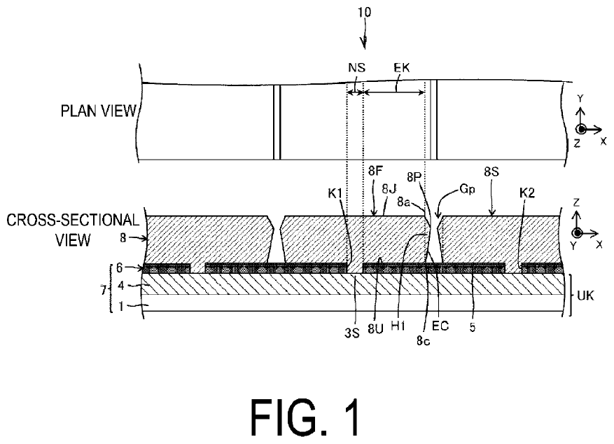

FIG. 1 is a plan view and a cross-sectional view illustrating a configuration of a semiconductor substrate according to the present embodiment. As illustrated in FIG. 1, a semiconductor substrate 10 (substrate wafer) according to the present embodiment includes a main substrate 1 (only the vicinity of an upper surface is illustrated), a mask pattern 6 located above the main substrate 1 and including a mask portion 5, and a first semiconductor part 8F and a second semiconductor part 8S located in a layer above the mask pattern 6 and adjacent to each other, and the first semiconductor part 8F has a first lower edge 8c located on the mask portion 5, and a first protruding portion H1 protruding toward the second semiconductor part 8S side farther than the first lower edge 8c in a plan view. The mask pattern 6 can be configured to include a first opening portion K1 and a second opening portion K2 adjacent to each other in a first direction (hereinafter, an X direction), and the mask portion 5 located between the first opening portion K1 and the second opening portion K2.

The first protruding portion H1 may have any overhang structure that overhangs farther than the first lower edge 8c in the X direction. An end face of the first protruding portion H1 in FIG. 1 includes two surfaces, but is not limited thereto, and may include only one surface or may include three or more surfaces. The surface included in the end face of the first protruding portion H1 may be flat or curved. The first protruding portion H1 may include the first lower edge 8c and may have a surface EC non-perpendicular to the X direction.

The semiconductor substrate 10 may have a configuration where it includes an underlying layer 4 including a seed portion 3 above the main substrate 1 and the first semiconductor part 8F is in contact with the seed portion 3S in the first opening portion K1. The first and second opening portions K1 and K2 may each have a tapered shape (a shape in which a width becomes narrower toward the underlying layer 4 side). The underlying layer 4 may be formed to overlap at least the first and second opening portions K1 and K2.

In the semiconductor substrate 10, a plurality of layers are layered on the main substrate 1, and a layering direction thereof may be defined as an “upward direction”. Seeing the semiconductor substrate 10 with a line of sight parallel to the normal direction of the semiconductor substrate 10 may be referred to as a “plan view”. The semiconductor substrate refers to a substrate including a semiconductor part, and the main substrate 1 may be a semiconductor or a non-semiconductor. In the specification, the main substrate 1 and the underlying layer 4 may be collectively referred to as a base substrate UK, and the main substrate 1, the underlying layer 4, and the mask pattern 6 may be collectively referred to as a template substrate (a substrate for ELO) 7.

The first semiconductor part 8F contains a nitride semiconductor, for example. The nitride semiconductor may be expressed, for example, by AlxGayInzN (0≤x≤1; 0≤y≤1; 0≤z≤1; x +y+z=1). Specific examples of the nitride semiconductor may include a GaN-based semiconductor, aluminum nitride (AlN), indium aluminum nitride (InAlN), and indium nitride (InN). The GaN-based semiconductor is a semiconductor containing gallium atoms (Ga) and nitrogen atoms (N). Typical examples of the GaN-based semiconductor may include GaN, AlGaN, AlGaInN, and InGaN. The first semiconductor part 8F may be of a doped type (for example, an n-type including a donor) or a non-doped type.

The first semiconductor part 8F including the GaN-based semiconductor may be formed by an epitaxial lateral overgrowth (ELO) method, but may alternatively be formed by another method as long as low defects can be realized. In the ELO method, for example, a heterogeneous substrate different from the GaN-based semiconductor in terms of lattice constant is used as the main substrate 1, the GaN-based semiconductor is used for the seed portion 3S, an inorganic compound film is used for the mask pattern 6, and the GaN-based first semiconductor part 8F can be laterally grown on the mask portion 5. In this case, a thickness direction (Z direction) of the first semiconductor part 8F can be used as the <0001> direction (c-axis direction) of the GaN-based crystal, a width direction (first direction, X direction) of each of the first and second opening portions K1 and K2 each having a longitudinal shape can be used as the <11-20> direction (a-axis direction) of the GaN-based crystal, and a longitudinal direction (Y direction) of each of the first and the second opening portions K1 and K2 can be used as the <1-100> direction (m-axis direction) of the GaN-based crystal. A layer formed by the ELO method may be referred to as an ELO semiconductor layer (including the first semiconductor part 8F).

The first semiconductor part 8F formed by the ELO method includes a dislocation inheritance portion NS overlapping the first opening portion K1 in a plan view and a low-defect portion EK (dislocation non-inheritance portion) overlapping the mask portion 5 in a plan view and having fewer threading dislocations than the dislocation inheritance portion NS. When a layer above the first semiconductor part 8F includes an active layer (for example, a layer in which electrons and holes are combined), the active layer can be provided to overlap the low-defect portion EK in a plan view.

A portion of the first semiconductor part 8F, which overlaps the mask portion 5 in a plan view, may be made of a GaN-based crystal body including a GaN-based semiconductor and having an upper surface 8J and a lower surface 8U parallel to the (0001) plane (c-plane). The GaN-based crystal body has a non-threading dislocation density in a cross section parallel to the <0001>direction that is substantially equal to or larger than a threading dislocation density in the upper surface 8J, and includes the lower edge 8c parallel to the <1-100> direction and the protruding portion (overhang portion) H1 protruding in the <11-20> direction farther than the lower edge. The cross section parallel to the <0001> direction is, for example, the (1-100) plane (m-plane) or the (11-20) plane (a-plane).

The threading dislocation is a dislocation (defect) extending from the lower surface or inside to the surface or surface layer of the first semiconductor part 8F along the thickness direction (Z direction) of the first semiconductor part 8F. Cathode luminescence (CL) measurement on the surface (parallel to the c-plane) of the first semiconductor part 8F enables observation of the threading dislocation. The non-threading dislocation is a dislocation measured by CL in a cross section taken along a plane parallel to the thickness direction, and is mainly a basal plane (c-plane) dislocation.

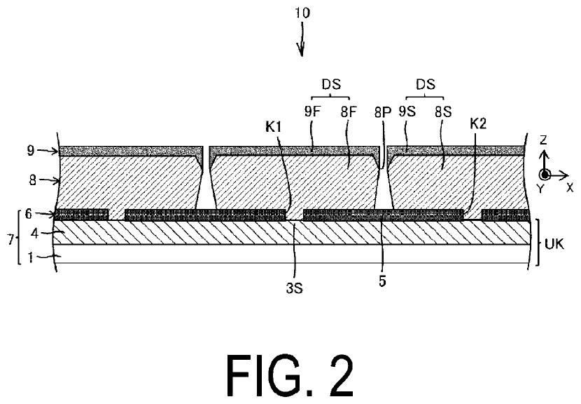

FIG. 2 is a cross-sectional view illustrating another configuration of the semiconductor substrate according to the present embodiment. As illustrated in FIG. 2, the semiconductor substrate 10 includes the main substrate 1, the underlying layer 4, the mask pattern 6, the first and second semiconductor parts 8F and 8S, a first function layer 9F in a layer above the first semiconductor part 8F, and a second function layer 9S in a layer above the second semiconductor part 8S, and the first semiconductor part 8F and the first function layer 9F overlap and the second semiconductor part 8S and the second function layer 9S overlap in a plan view. Each of the first and second function layers 9F and 9S may be a single layer body or a laminate body.

The first function layer 9F may have at least one selected from the group consisting of a function as a constituent element of a semiconductor device, an optical function, and a sensing function.

As illustrated in FIG. 2, since the first semiconductor part 8F has the first protruding portion H1, when forming the first and second function layers 9F and 9S, it is difficult for a raw material to reach the mask portion 5 located between the first and second semiconductor parts 8F and 8S, and therefore, formation of a deposit is reduced. Since it is difficult for the first function layer 9F formed in a layer above the first semiconductor part 8F to be formed below a top portion 8P of the first protruding portion H1, the first function layer 9F and the second function layer 9S are less likely to be connected to each other.

### Manufacturing Semiconductor Substrate

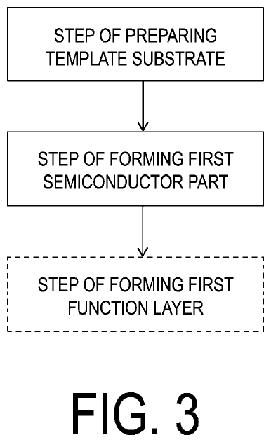

FIG. 3 is a flowchart illustrating an example of a manufacturing method for manufacturing the semiconductor substrate according to the present embodiment. In the method for manufacturing the semiconductor substrate in FIG. 3, after a step of preparing the template substrate (substrate for ELO growth) 7, a step of forming the first semiconductor part 8F by using the ELO method is performed. After the step of forming the first semiconductor part 8F, a step of forming the first function layer 9F may be performed as necessary. In the step of preparing the template substrate 7, the mask pattern 6 may be formed on the underlying substrate UK.

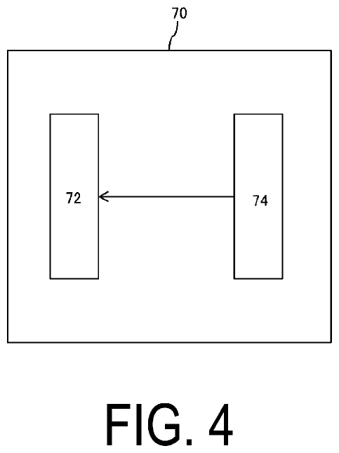

FIG. 4 is a block diagram illustrating an example of a manufacturing apparatus for manufacturing the semiconductor substrate according to the present embodiment. A manufacturing apparatus 70 for manufacturing the semiconductor substrate illustrated in FIG. 4 includes a semiconductor former 72 that forms the first and second semiconductor parts 8F and 8S adjacent to each other in the X direction (first direction) on the template substrate 7, and a controller 74 that controls the semiconductor former 72. The semiconductor former 72 forms the first semiconductor part 8F (see FIG. 1) having the first lower edge 8c located on the mask portion 5 and the first protruding portion H1 protruding in the X direction (a-axis direction) farther than the first lower edge 8F in a plan view by the ELO method. The manufacturing apparatus 70 for manufacturing the semiconductor substrate may be configured to form the first function layer 9F.

The semiconductor former 72 may include an MOCVD device, and the controller 74 may include a processor and a memory. The controller 74 may be configured to control the semiconductor former 72 by executing a program stored in a built-in memory, a communicable communication device, or an accessible network, for example, and the present embodiment also includes the program, and a recording medium storing the program therein.

### Manufacturing Semiconductor Device

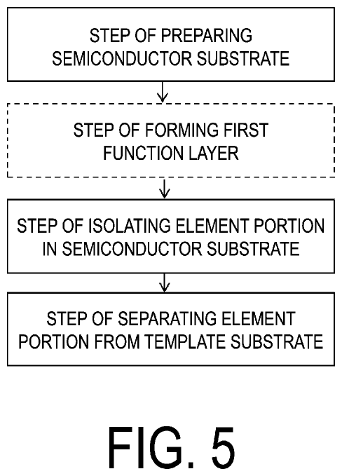

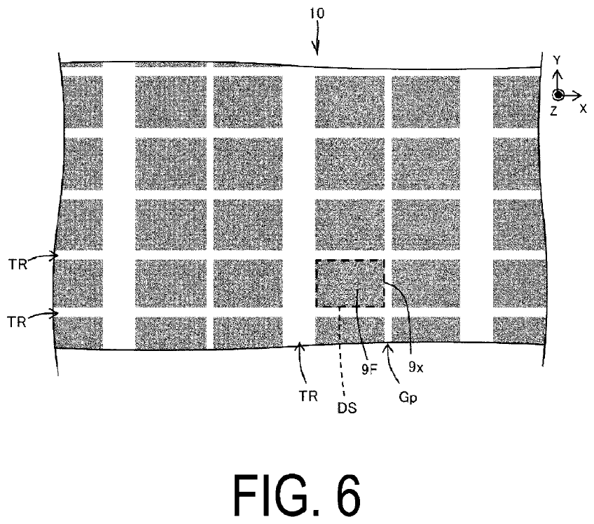

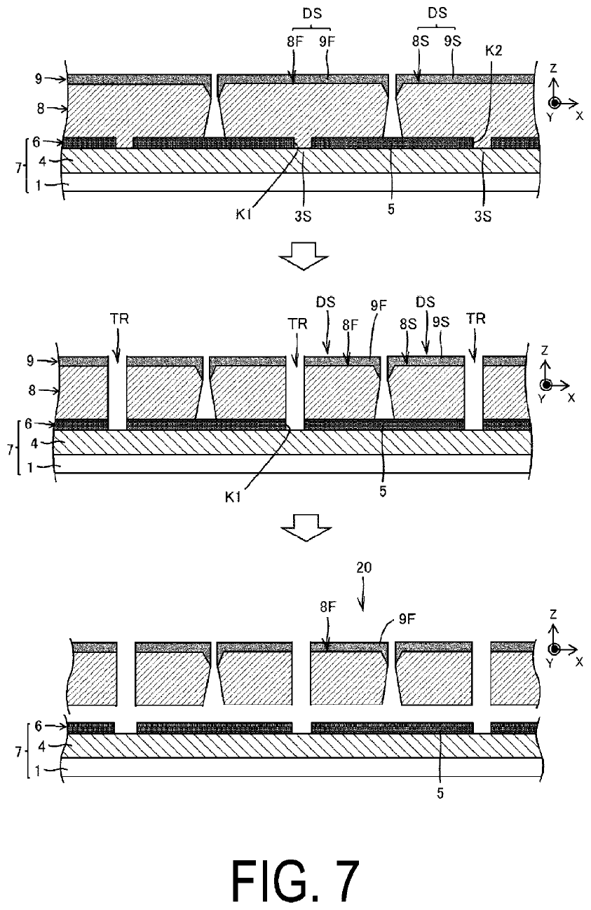

FIG. 5 is a flowchart illustrating an example of a manufacturing method for manufacturing a semiconductor device according to the present embodiment. FIG. 6 is a plan view illustrating an example of isolation of an element portion. FIG. 7 is a cross-sectional view illustrating an example of isolation and separation of the element portion. In the manufacturing method for manufacturing the semiconductor device in FIG. 5, after a step of preparing the semiconductor substrate 10, a step of forming the first function layer 9F on the first semiconductor part 8F is performed as necessary. Thereafter, as illustrated in FIGS. 6 and 7, a step of isolating element portions DS (including the low-defect portion EK of the first semiconductor part 8F and the first function layer 9F) from each other by forming a plurality of trenches TR (isolation grooves) in the semiconductor substrate 10 is performed. The trench TR penetrates through the first function layer 9F and the first semiconductor part 8F. The trench TR may expose the underlying layer 4 and the mask portion 5. An opening width of the trench TR may be equal to or greater than a width of the first opening portion K1. At this stage, each element portion DS is bonded to the mask portion 5 by van der Waals bonding, and is part of the semiconductor substrate 10.

Subsequently, as illustrated in FIG. 7, a step of separating the element portion DS from the template substrate 7 to form a semiconductor device 20 is performed. The first function layer 9F of the isolated element portion DS includes an end face 9x perpendicular to the X direction. However, since the end face 9x is not subjected to end face erosion due to etching, the first function layer 9F (particularly, the active layer) of good quality is realized. Note that the step of preparing the semiconductor substrate 10 in FIG. 5 may include each step of the manufacturing method for manufacturing the semiconductor substrate illustrated in FIG. 3.

### Semiconductor Device

As illustrated in FIG. 7, by separating the element portion DS from the template substrate 7, a semiconductor device 20 (containing, for example, a GaN-based crystal body) can be formed. As a separation method, the semiconductor device 20 may be bonded to another carrier substrate by using solder, or may be peeled off using an adhesive stamp made of an adhesive material or a flexible material such as polydimethylsiloxane (PDMS), which is a silicone elastomer.

Specific examples of the semiconductor device 20 include a light emitting diode (LED), a semiconductor laser, a Schottky diode, a photodiode, and transistors (including a power transistor and a high electron mobility transistor).

### Electronic Device

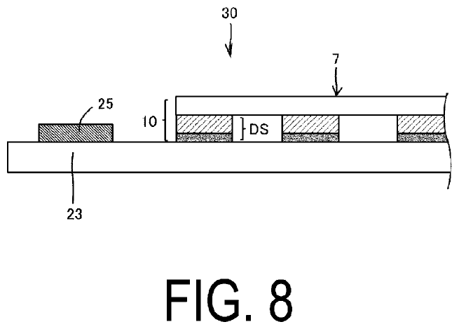

FIG. 8 is a schematic view illustrating a configuration of an electronic device according to the present embodiment. An electronic device 30 in FIG. 8 includes the semiconductor substrate 10 (configured to function as a semiconductor device with the template substrate 7 included, for example, in a case where the template substrate 7 is light-transmissive), a drive substrate 23, on which the semiconductor substrate 10 is mounted, and a control circuit 25 that controls the drive substrate 23.

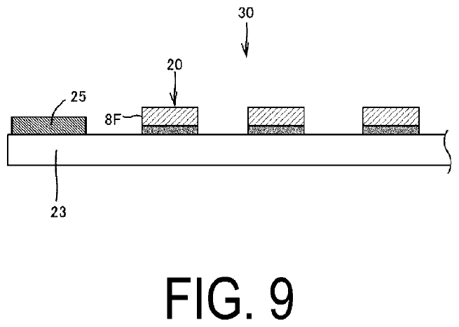

FIG. 9 is a schematic view illustrating another configuration of the electronic device according to the present embodiment. An electronic device 30 in FIG. 9 includes the semiconductor device 20 including at least the low-defect portion EK, the drive substrate 23 on which the semiconductor device 20 is mounted, and the control circuit 25 that controls the drive substrate 23.

Examples of the electronic device 30 include display devices, laser emitting devices (including a Fabry-Perot type and a surface emitting type), lighting devices, communication devices, information processing devices, sensing devices, and electrical power control devices.

### Example 1

### Overall Configuration

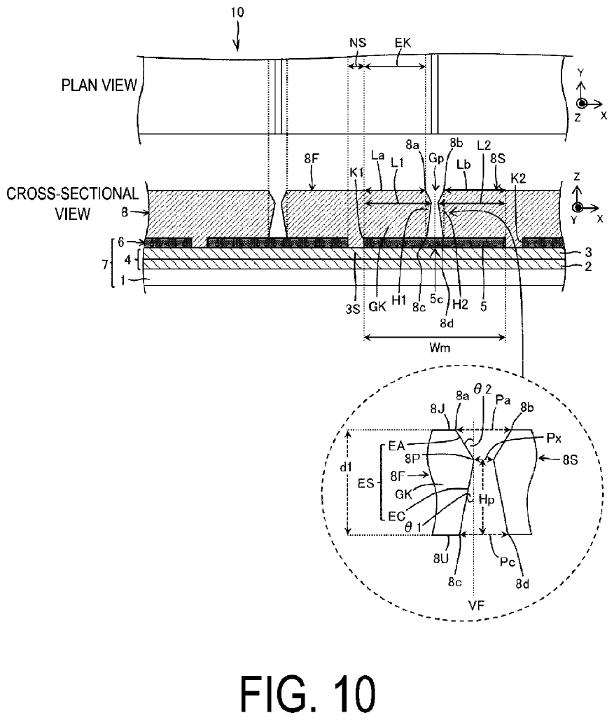

FIG. 10 is a plan view and a cross-sectional view illustrating a configuration of a semiconductor substrate according to Example 1. As illustrated in FIG. 10, the semiconductor substrate 10 according to Example 1 includes the main substrate 1, the underlying layer 4 located above the main substrate 1, the mask pattern 6 including the first and second opening portions K1 and K2 adjacent to each other in the X direction and the mask portion 5 located between the first and second opening portions K1 and K2, and the first and second semiconductor parts 8F and 8S located in a layer above the mask pattern 6. The first and second semiconductor parts 8F and 8S are formed by the ELO method, isolated from each other, and adjacent to each other. Note that the first and second semiconductor parts 8F and 8S may be referred to as an ELO semiconductor layer 8. The first and second semiconductor parts 8F and 8S may also be referred to as first and second semiconductor layers.

The first semiconductor part 8F has the first protruding portion H1 overlapping the first opening portion K1 and protruding in the X direction (toward the second semiconductor part 8S side) farther than the first lower edge 8c in a plan view. The second semiconductor part 8S has a second protruding portion H2 overlapping the second opening portion K2 and protruding in a direction opposite to the X direction (toward the first semiconductor part 8F side) farther than a second lower edge 8d in a plan view. The lower edge refers to, for example, an edge of a lower surface of the semiconductor layer part, and the upper edge refers to, for example, an edge of an upper surface of the semiconductor layer part.

### Main Substrate

A heterogeneous substrate different from the GaN-based semiconductor in terms of lattice constant may be used for the main substrate 1. Examples of the heterogeneous substrate include a single crystal silicon (Si) substrate, a sapphire (Al₂O₃) substrate, and a silicon carbide (SiC) substrate. The plane orientation of the main substrate 1 is, for example, the (111) plane of the silicon substrate, the (0001) plane of the sapphire substrate, or the 6H-SiC (0001) plane of the SiC substrate. These are merely examples, and any main substrate and any plane orientation may be used as long as the ELO semiconductor layer 8 can be grown by the ELO method.

### Underlying Layer

As the underlying layer 4, a buffer layer 2 (for example, an AlN layer) and a seed layer 3 (for example, a nitride semiconductor) may be provided in that order from the main substrate side. The buffer layer 2 has, for example, a function of reducing the likelihood of the main substrate 1 and the seed layer 3 coming into direct contact with each other and melting together. In a silicon substrate or the like used for the main substrate 1, the main substrate 1 and the GaN-based semiconductor serving as the seed layer 3 melt together. Thus, for example, providing the buffer layer 2 such as an AlN layer can suppress such a melting. For example, when the main substrate 1 unlikely to melt together with the seed layer 3, which is a GaN-based semiconductor, is used, a configuration may be employed in which the buffer layer 2 is not provided. The AlN layer being an example of the buffer layer 2 can be formed using an MOCVD device, for example, to have a thickness of from about 10 nm to about 5 μm. The buffer layer 2 may have the effect of enhancing the crystallinity of the seed layer 3 and/or the effect of relaxing the internal stress of the ELO semiconductor layer 8.

For example, a GaN-based semiconductor containing Al may be used for the seed layer 3. The seed layer 3 includes a seed portion 3S (a growth starting point of the ELO semiconductor layer) overlapping the first opening portion K1 of the mask pattern 6. As the seed layer 3, a graded layer in which the Al composition approaches GaN in a graded manner may be used. The graded layer is a laminate body provided with, for example, an Al_{0.7}Ga_{0.3}N layer as a first layer and an Al_{0.3}Ga_{0.7}N layer as a second layer in order from the buffer layer side. In this case, a composition ratio of Ga (0.7/2=0.35) in the second layer (Al:Ga:N=0.3:0.7:1) is larger than a composition ratio of Ga (0.3/2=0.15) in the first layer (Al:Ga:N=0.7:0.3:1). The graded layer may be easily formed by the MOCVD method and may be composed of three or more layers. By using the graded layer for the seed layer 3, stress from the main substrate 1 as the heterogeneous substrate may be alleviated. The seed layer 3 may include a GaN layer. In this case, the seed layer 3 may be a GaN single layer, or the uppermost layer of the graded layer as the seed layer 3 may be a GaN layer.

The buffer layer 2 (for example, aluminum nitride) and/or the seed layer 3 (for example, GaN-based semiconductor) may be film-formed using a sputtering device (PSD: pulse sputter deposition, PLD: pulsed laser deposition, or the like).

### Mask Pattern

The mask pattern 6 (mask layer) includes the mask portion 5 and the first and second opening portions K1 and K2. The first and second opening portions K1 and K2 may have a function of a growth start hole for exposing the seed portion 3S and starting growth of the ELO semiconductor layer 8, and the mask portion 5 may have a function of a selective growth mask for laterally growing the ELO semiconductor layer 8. The first and second opening portions K1 and K2 are portions where the mask portion 5 in the mask pattern 6 is not present (non-formed portions), and need not be surrounded by the mask portion 5.

As the mask pattern 6, for example, a single-layer film including any one of a silicon oxide film (SiOx), a titanium nitride film (TiN or the like), a silicon nitride film (SiNx), a silicon oxynitride film (SiON), and a metal film having a high melting point (for example, 1000° C. or higher), or a layered film including at least two thereof may be used.

For example, a silicon oxide film having a thickness of from about 100 nm to about 4 μm (preferably from about 150 nm to about 2 μm) is formed on the entire surface of the underlying layer 4 by using sputtering, and a resist is applied onto the entire surface of the silicon oxide film. Thereafter, the resist is patterned by photolithography to form the resist having a plurality of stripe-shaped opening portions. Thereafter, a part of the silicon oxide film is removed by a wet etchant such as hydrofluoric acid (HF), buffered hydrofluoric acid (BHF), or the like to form the plurality of opening portions (including K1 and K2), and the resist is removed by organic cleaning to form the mask pattern 6.

The first and second opening portions K1 and K2 each have a rectangular shape (slit shape) and are periodically aligned in the a-axis direction (X direction) of the ELO semiconductor layer 8. The widths of the first and second opening portions K1 and K2 are from about 0.1 μm to about 20 μm. As the width of each opening portion is smaller, the number of threading dislocations propagating from each opening portion to the ELO semiconductor layer 8 is reduced. This also facilitates the peeling off (separation) of the ELO semiconductor layer 8 from the template substrate 7 in a post process. An area of the low-defect portion EK (for example, GaN-based crystal body) with few surface defects can be increased.

The silicon oxide film may be decomposed and evaporated in a small amount during film formation of the ELO semiconductor layer 8 and may be taken into the ELO semiconductor layer 8, while the silicon nitride film and the silicon oxynitride film have the advantage of being difficult to decompose and evaporate at a high temperature.

The mask pattern 6 may be a single-layer film of a silicon nitride film or a silicon oxynitride film, a layered film in which a silicon oxide film and a silicon nitride film are formed in that order on the underlying layer 4, a laminate body film in which a silicon nitride film and a silicon oxide film are formed in that order on the underlying layer 4, or a layered film in which a silicon nitride film, a silicon oxide film, and a silicon nitride film are formed in that order on the underlying layer.

An abnormal portion such as a pinhole in the mask portion 5 may be eliminated by performing organic cleaning or the like after film formation and introducing the film again into a film forming device to form the same type of film. The mask pattern 6 with a high quality may be formed by using a general silicon oxide film (single layer) and using the above-described re-film formation method.

### Specific Example of Template Substrate

A silicon substrate having the (111) plane was used as the main substrate 1, and the buffer layer 2 of the underlying layer 4 was an AlN layer (for example, 30 nm). The seed layer 3 of the underlying layer 4 was a graded layer in which an Al_{0.6}Ga_{0.4}N layer (for example, 300 nm) as a first layer and a GaN layer (for example, from 1 to 2 μm) as a second layer were formed in that order. That is, the composition ratio of Ga (½=0.5) in the second layer (Ga:N=1:1) is larger than the composition ratio of Ga (0.6/2=0.3) in the first layer (Al:Ga:N=0.6:0.4:1).

As the mask pattern 6, a laminate body in which a silicon oxide film (SiO₂) and a silicon nitride film (SiN) were formed in that order was used. The silicon oxide film had a thickness of, for example, 0.3 μm, and the silicon nitride film had a thickness of, for example, 70 nm. Each of the silicon oxide film and the silicon nitride film was film-formed by a plasma chemical vapor deposition (CVD) method.

### Film Formation of ELO Semiconductor Layer

In Example 1, the ELO semiconductor layer 8 was a GaN layer, and ELO film formation of gallium nitride (GaN) was performed on the template substrate 7 by using the MOCVD device included in the semiconductor former 72 in FIG. 4. The following may be adopted as examples of the ELO film formation conditions: substrate temperature: 1120° C., growth pressure: 50 kPa, trimethylgallium (TMG): 22 sccm, NH₃: 15 slm, and V/III=6000 (ratio of group V raw material supply amount to group III raw material supply amount).

In this case, the first and second semiconductor parts 8F and 8S are selectively grown on the seed portion 3S (the GaN layer that is the uppermost layer of the seed layer 3) exposed in the first and second opening portions K1 and K2, and are subsequently laterally grown on the mask portion 5. The lateral growth was stopped before the first and second semiconductor parts 8F and 8S laterally grown from both sides of the mask portion 5 met each other. Before the growth of the first and second semiconductor parts 8F and 8S is stopped, a period may be included in which a lower interval Pc in FIG. 10 is not substantially changed and an area of a lower inclined surface EC is enlarged in an overhang state.

A width Wm of the mask portion 5 was 50 μm, widths of the first and second opening portions K1 and K2 were 5 μm, a lateral width of the ELO semiconductor layer 8 was 53 μm, a width (size in the X direction) of the low-defect portion EK was 24 μm, and a layer thickness of the ELO semiconductor layer 8 was 5 μm. An aspect ratio of the ELO semiconductor layer 8 was 53 μm/5 μm=10.6, and a very high aspect ratio was achieved.

In the film formation of the ELO semiconductor layer 8, interaction between the ELO semiconductor layer 8 and the mask portion 5 is preferably reduced, and a state in which the ELO semiconductor layer 8 and the mask portion 5 are in contact with each other by van der Waals force is preferably made.

In the formation of the ELO semiconductor layer 8 in Example 1, the lateral film formation rate is increased. The method for increasing the lateral film formation rate is as follows. First, a longitudinal growth layer that grows in the Z direction (c-axis direction) is formed on the seed portion 3S exposed from the first and second opening portion K1 and K2, and then a lateral growth layer that grows in the X direction (a-axis direction) is formed. In this case, the thickness of the longitudinal growth layer being 10 μm or thinner, 5 μm or thinner, 3 μm or thinner, or 1 μm or thinner allows the thickness of the lateral growth layer to be reduced so as to be thin, increasing the lateral film formation rate.

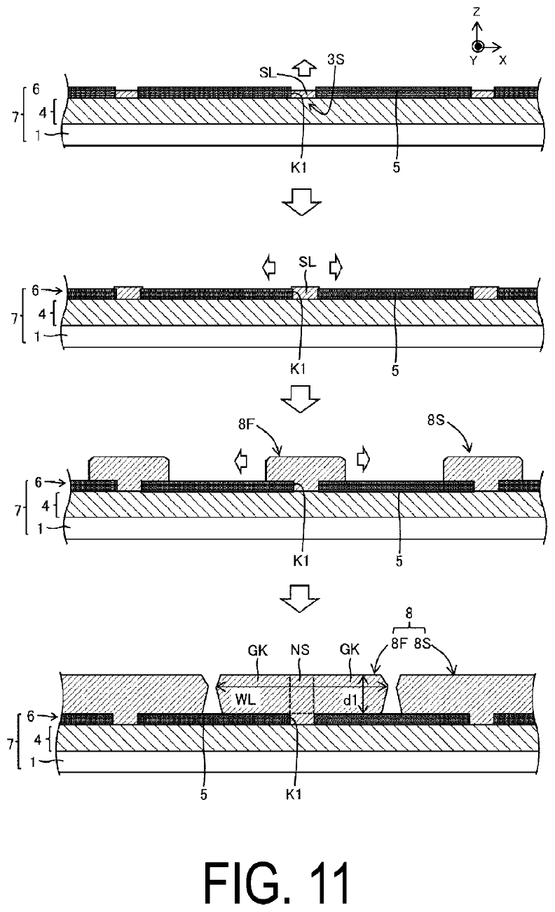

FIG. 11 is a cross-sectional view illustrating an example of lateral growth of an ELO semiconductor layer. As illustrated in FIG. 11, an initial growth layer (a part of the dislocation inheritance portion NS) SL is formed on the seed portion 3S, and then the first and second semiconductor parts 8F and 8S are desirably grown laterally from the initial growth layer SL. The initial growth layer SL serves as a start point of the lateral growth of the first and second semiconductor parts 8F and 8S. The first and second semiconductor parts 8F and 8S may be controlled to grow in the Z direction (c-axis direction) or in the X direction (a-axis direction) by appropriately controlling the ELO film formation conditions. The shapes of the first and second protruding portions H1 and H2 shown in FIG. 10 can also be controlled by the ELO film formation conditions (X-direction growth conditions).

For the film formation of the first and second semiconductor parts 8F and 8S, a method may be used in which the film formation of the initial growth layer SL is stopped at a timing immediately before an edge of the initial growth layer SL rides on the upper surface of the mask portion 5 (at a stage of being in contact with the upper end of a side surface of the mask portion 5) or immediately after the edge of the initial growth layer SL rides on the upper surface of the mask portion 5 (that is, at this timing, the ELO film formation condition is switched from the c-axis direction film formation condition to the a-axis direction film formation condition). With this, since the lateral film formation starts from a state where the initial growth layer SL slightly protrudes from the mask portion 5, the material consumed for the growth in the thickness direction may be reduced, and the first and second semiconductor parts 8F and 8S may be grown laterally at a high speed. The initial growth layer SL may be formed to have a thickness of from 50 nm to 5.0 μm (for example, from 80 nm to 2 μm). The thickness of the mask portion 5 and the thickness of the initial growth layer SL may be 500 nm or thinner.

By laterally growing the first and second semiconductor parts 8F and 8S after the initial growth layer SL is film-formed as illustrated in FIG. 11, the number of non-threading dislocations inside the low-defect portion EK can be increased (threading dislocation density on the surface of the low-defect portion EK can be reduced). The distribution of the impurity concentration (for example, silicon or oxygen) inside the low-defect portion EK may be controlled.

With the method in FIG. 11, the aspect ratio (ratio of the size in the X direction to the thickness=WL/d1) of the first semiconductor part 8F is markedly increased to 3.5 or more, 5.0 or more, 6.0 or more, 8.0 or more, 10 or more, 15 or more, 20 or more, 30 or more, or 50 or more. With the method in FIG. 11, the ratio of the width (WL) of the first semiconductor part 8F to the width of the first opening portion K1 may be 3.5 or more, 5.0 or more, 6.0 or more, 8.0 or more, 10 or more, 15 or more, 20 or more, 30 or more, or 50 or more, and the ratio of the low-defect portion EK may be increased. The first and second semiconductor parts 8F and 8S illustrated in FIG. 11 may be a nitride semiconductor crystal (for example, a GaN crystal, an AlGaN crystal, an InGaN crystal, or an InAlGaN crystal).

As an example, by reducing the supply amount of ammonia and forming the film at a low V/III (<1000) or so, when the film formation in the lateral direction proceeds, the inversely tapered shape is easily formed. This is presumed to be because, in the facet film formation of the side surface portion of the ELO semiconductor layer 8, an inversely tapered crystal plane is easily formed. When film formation at a low V/III (<1000) is performed at a temperature below 1000° C., triethylgallium (TEG) is preferably used as a gallium raw material gas. Since an organic raw material is efficiently decomposed at a low temperature with TEG as compared with TMG, the lateral film formation rate may be increased.

As another example, when the thickness of the vertical growth layer (initial growth layer) is set to 2 μm or more and the film formation is finished before the films laterally grown on the mask portion 5 meet each other, it is difficult for the Ga raw material and the ammonia raw material to be supplied to the gap portion due to the thickness of the vertical growth layer, and therefore, the growth of the lower side of the end face of the ELO semiconductor layer 8 can be suppressed. In this case, when film formation is performed at a high temperature (for example, a film-forming temperature of 1050° C. or higher) and under a condition of high V/III (>5000) or so, an inversely tapered crystal plane is easily obtained.

The film-forming temperature of the ELO semiconductor layer 8 is preferably 1150° C. or less rather than a high temperature exceeding 1200° C. The ELO semiconductor layer 8 may be formed even at a low temperature below 1000° C., which is more preferable from the viewpoint of reducing the interaction. It has been found that in such low-temperature film formation, when trimethyl gallium (TMG) is used as a gallium raw material, the raw material is not sufficiently decomposed, and gallium atoms and carbon atoms are simultaneously taken into the ELO semiconductor layer 8 in larger quantities than usual. The reason for this may be as follows: in the ELO method, since the film formation in the a-axis direction is fast and the film formation in the c-axis direction is slow, the above atoms are taken in during the c-plane film formation in large quantities.

It has been found that the carbon taken into the ELO semiconductor layer 8 reduces a reaction with the mask portion 5, and reduces adhesion or the like between the mask portion 5 and the ELO semiconductor layer 8. Thus, in the low-temperature film formation of the ELO semiconductor layer 8, the supply amount of ammonia is reduced and the film formation is performed at a low V/III (<1000), thereby making it possible to take the carbon elements in the raw material or a chamber atmosphere into the ELO semiconductor layer 8 and to reduce the reaction with the mask portion 5. In this case, the ELO semiconductor layer (first and second semiconductor parts 8F and 8S) contains carbon.

### Shape Example of ELO Semiconductor Layer

In the semiconductor substrate 10 in FIG. 10, the first semiconductor part 8F has a first upper edge 8a located between a mask-portion center 5c and the first opening portion K1 in a plan view, a first lower edge 8c (located on the mask portion 5) located between the mask-portion center 5c and the first opening portion K1 in a plan view, and a first protruding portion H1 protruding in the X direction (toward the second semiconductor part 8S side) farther than the first lower edge 8c in a plan view.

The second semiconductor part 8S has a second upper edge 8b located between the mask-portion center 5c and the second opening portion K2 in a plan view, a second lower edge 8d (located on the mask portion 5) located between the mask-portion center 5c and the second opening portion K2 in a plan view, and a second protruding portion H2 protruding in the X direction (toward the first semiconductor part 8F side) farther than the second lower edge 8d in a plan view.

Portions of the first and second semiconductor parts 8F and 8S, which overlap the mask portion 5 in a plan view, are a GaN-based crystal body GK including a GaN-based semiconductor and having an upper surface 8J and a lower surface 8U parallel to the (0001) plane (c-plane). The GaN-based crystal body GK has a non-threading dislocation density in a cross section parallel to the <0001> direction larger than a threading dislocation density in the upper surface 8J, and includes the lower edge 8c parallel to the <1-100> direction and the protruding portion (overhang portion) H1 protruding in the <11-20> direction farther than the lower edge.

The non-threading dislocation density of the GaN-based crystal body GK may be 10 times or more, for example, 20 times or more than the threading dislocation density. The threading dislocation density may be, for example, 5×10⁶ [pieces/cm²] or less. The width (size in the X direction) of the GaN-based crystal body GK may be, for example, 10 μm or greater. In the GaN-based crystal body GK, threading dislocations that affect characteristics of the semiconductor device are suppressed, while the presence of non-threading dislocations that hardly affect the characteristics of the semiconductor device also has an effect of relaxing film stress.

Regarding the GaN-based crystal body GK, the non-threading dislocation density in a cross section taken along a plane parallel to the (11-20) plane (a-plane) may be larger than the non-threading dislocation density in a cross-section taken along a plane parallel to the (1-100) plane (m-plane). Since the GaN-based crystal body GK is formed by lateral (X direction) growth, the concentration of impurities (atoms contained in the mask pattern 6, for example, silicon or oxygen) may be low, as compared with one end portion corresponding to the growth initial stage, at the other end portion corresponding to the growth termination stage in the X direction (first direction).

In Example 1, in the X direction, a maximum distance L1 between the first opening portion K1 and the first protruding portion H1 is larger than a distance La between the first opening portion K1 and the first upper edge 8a, and in the X direction, and a maximum distance L2 between the second opening portion K2 and the second protruding portion H2 is larger than a distance Lb between the second opening portion K2 and the second upper edge 8b.

A side surface ES of the first semiconductor part includes a lower inclined surface EC including the first lower edge 8c and an upper inclined surface EA including the first upper edge 8a, and a first acute angle θ1 formed by the lower inclined surface EC and a plane VF perpendicular to the X direction is smaller than a second acute angle θ2 formed by the upper inclined surface EA and the plane VF perpendicular to the X direction. The first acute angle θ1 may be 30° or less, 20° or less, or 15° or less. A distance Hp between the mask portion 5 and the top portion 8P of the first protruding portion is larger than a half of a thickness d1 of the first semiconductor part 8F. The second acute angle θ2 may be 75° or greater, 80° or greater, or 85° or greater.

A minimum interval Px between the first semiconductor part 8F and the second semiconductor part 8S is smaller than a lower interval Pc indicating an interval between the first lower edge 8c and the second lower edge 8d and an upper interval Pa indicating an interval between the first upper edge 8a and the second upper edge 8b, and the upper interval Pa is larger than the lower interval Pc. The minimum interval Px is, for example, 5 μm or less, the lower interval Pc is, for example, 7 μm or less, and the upper interval Pa is, for example, 8 μm or less. The lower interval Pc may be smaller than the opening widths of the first and second opening portions K1 and K2. The minimum interval Px may be smaller than the opening widths of the first and second opening portions K1 and K2.

As described above, the gap (gap space) Gp is provided between the first and second semiconductor parts 8F and 8S adjacent to each other, so that internal stress of the ELO semiconductor layer 8 can be reduced, and cracks and defects generated in the ELO semiconductor layer 8 can be reduced. This effect is particularly large when the main substrate 1 is a heterogeneous substrate.

### Function Layer

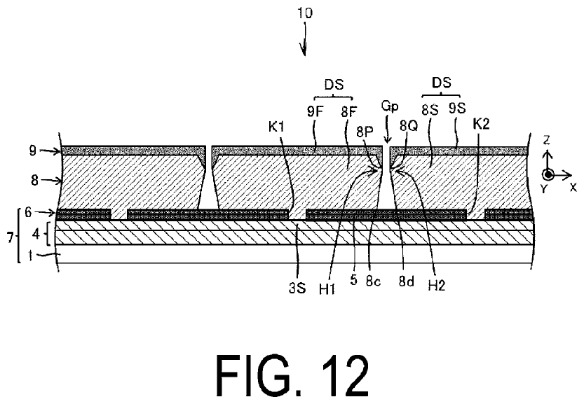

FIG. 12 is a cross-sectional view illustrating another configuration of the semiconductor substrate according to Example 1. In FIG. 12, the first function layer 9F is arranged on the first semiconductor part 8F, and the second function layer 9S is arranged on the second semiconductor part 8S. The function layer 9 (including the first and second function layers 9F and 9S) may be configured to include, for example, at least one selected from the group consisting of an n-type semiconductor layer (for example, GaN-based), a non-doped semiconductor layer (for example, GaN-based), a p-type semiconductor layer (for example, GaN-based), an electrically conductive layer, and an insulation layer. The non-doped semiconductor layer may be used as an active layer (a layer in which electrons and holes are combined). The function layer 9 may be formed by an arbitrary method.

Since the first semiconductor part 8F has the first protruding portion H1 and the second semiconductor part 8S has the second protruding portion H2, when forming the first and second function layers 9F and 9S, it is difficult for raw materials (aluminum source, indium source) and the like to reach the mask portion 5 located between the first and second semiconductor parts 8F and 8S, and therefore, formation of deposits is reduced. It is also possible to suppress the function layers 9F and 9S from being connected to each other.

As illustrated in FIG. 12, since it is difficult for the first function layer 9F formed in a layer above the first semiconductor part 8F to be formed below the top portion 8P of the first protruding portion H1, and it is difficult for the second function layer 9S formed in a layer above the second semiconductor part 8S to be formed below the top portion 8Q of the second protruding portion H2, the first and second function layers 9F and 9S are naturally isolated during formation (self-isolation). This improves the yield for the step of isolating the element portion DS. In particular, the active layer included in the first function layer 9F preferably has a shape that does not reach the first lower edge 8c, and the active layer included in the second function layer 9S preferably has a shape that does not reach the second lower edge 8d.

When, for example, a GaN-based p-type semiconductor layer is formed in the function layer 9, silicon and oxygen isolated from the silicon-based mask pattern 6 (for example, a silicon oxide film) may be taken in to compensate for the p-type dopant (for example, Mg). When the ELO semiconductor layer 8 is a GaN-based n-type semiconductor, silicon or the like may also be isolated from the ELO semiconductor layer 8. In Example 1, since an n-type dopant such as silicon is suppressed by the first and second protruding portions H1 and H2, it is difficult for the n-type dopant to be taken into the p-type semiconductor layer, and therefore, the function of the p-type semiconductor layer can be enhanced.

In the case where the first function layer 9F includes a layer containing indium as a composition (for example, an InₓGa₍₁₋ₓ₎N layer, x is a positive number of 1 or less), since In atoms are larger than Ga atoms, crystal defects and in-film stress may occur due to lattice mismatch with the ELO semiconductor layer 8. However, since the first function layer 9F is separated from other function layers, propagation of the crystal defects can be suppressed and the in-film stress can be relaxed. In the case where the first function layer 9F includes a layer containing aluminum as a composition (for example, an AlₓGa₍₁₋ₓ₎N layer, x is a positive number of 1 or less), when the composition of Al increases, crystal defects such as cracks and crystal slip on a crystal plane (for example, m-plane slip in a GnN-based semiconductor layer) and in-film stress may occur due to lattice mismatch with the ELO semiconductor layer 8. However, since the first function layer 9F is separated from other function layers, propagation of the crystal defects can be suppressed and the in-film stress can be relaxed.

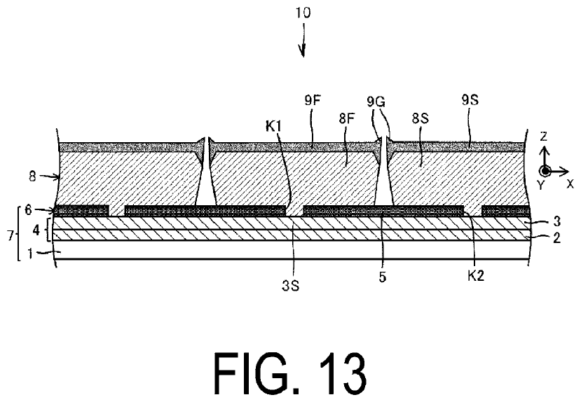

FIG. 13 is a cross-sectional view illustrating another configuration of the semiconductor substrate according to the present embodiment. When forming the function layer 9, an edge growth 9G (corner portion) may be generated as illustrated in FIG. 13. The edge growth is generated when the function layer 9 includes an AlGaN layer, for example. The edge growth may result in sizes of a width of 10 μm or more and a height of from about 200 nm to about 300 nm, and becomes an obstacle in a post process. However, by suppressing the minimum width Px (minimum gap) of the gap Gp below 10 μm, the edge growth 9G may be significantly reduced (for example, to a height of 100 nm or less).

### Isolation and Separation of Element Portion

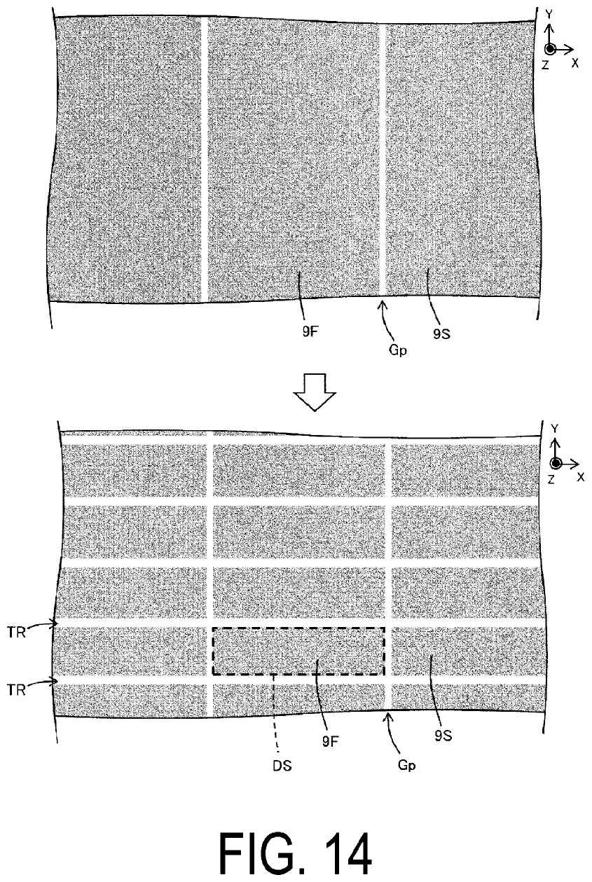

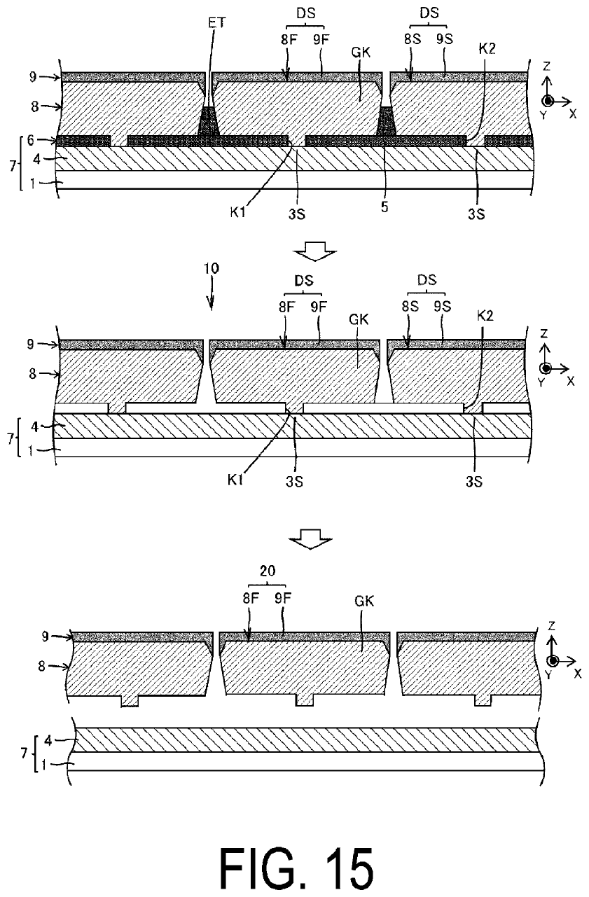

FIG. 14 is a plan view illustrating a step of isolating an element portion in Example 1. FIG. 15 is a cross-sectional view illustrating a step of separating an element portion in Example 1. In Example 1, as illustrated in FIG. 14, a plurality of trenches TR extending in the X direction are formed by dry etching to isolate the element portions DS. When seen in a plan view, the element portion DS is surrounded by two trenches TR and two gaps Gp extending in the Y direction, and the element portion DS larger than that in FIG. 6 can be isolated. The dry etching is implemented by a general photolithography method. After completion of the etching, a photoresist having served as a mask for the etching needs to be removed. However, for example, when organic cleaning using weak ultrasonic waves is carried out, the element portion DS is less likely to be peeled off from the mask portion 5.

After the isolation of the element portion DS, as illustrated in FIG. 15, the semiconductor substrate 10 may be immersed in an etchant ET to dissolve the mask pattern 6, an adhesive tape (for example, an adhesive dicing tape used for dicing a semiconductor wafer) may be attached to a surface of the ELO semiconductor layer 8, and then the temperature of the semiconductor substrate 10 with the adhesive tape attached thereto as is may be lowered to a low temperature by using a Peltier element (not illustrated). At this time, the adhesive tape, which generally has a larger thermal expansion coefficient than that of a semiconductor, contracts largely, and stress is thus applied to the ELO semiconductor layer 8. Since the ELO semiconductor layer 8 is bonded only to the underlying layer 4 (seed portion) of the template substrate 7 and the mask portion 5 has been removed, the stress from the adhesive tape is effectively applied to a bonding portion with the underlying layer 4 (of the template substrate 7), so that the bonding portion can be mechanically cleaved or broken. That is, etching is not needed for the removal of the bonding portion. Configuration with Dislocation Inheritance Portion Removed

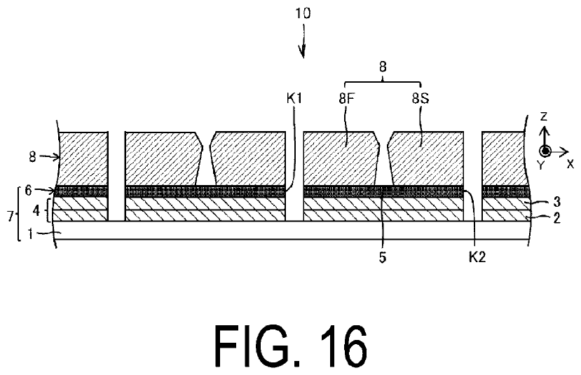

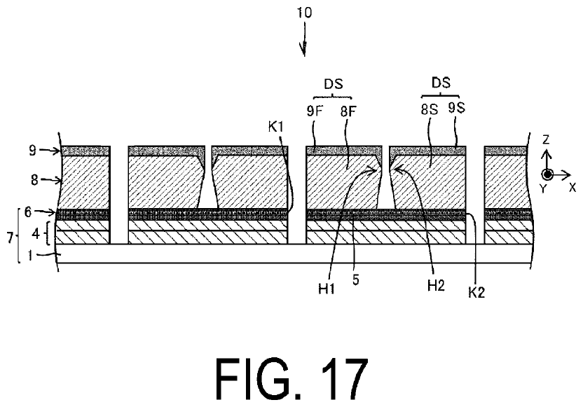

FIG. 16 is a cross-sectional view illustrating another configuration of the semiconductor substrate of Example 1. As illustrated in FIG. 16, the dislocation inheritance portions NS of the first and second semiconductor parts 8F and 8S (portions overlapping the first and second opening portions K1 and K2 in a plan view) may be removed from the semiconductor substrate 10 in FIG. 10. Portions of the underlying layer 4 that overlap the first and second opening portions K1 and K2 in a plan view can also be removed. FIG. 17 is a cross-sectional view illustrating another configuration of the semiconductor substrate 10 of Example 1. As illustrated in FIG. 17, the first and second function layers 9F and 9S may be provided on the first and second semiconductor parts 8F and 8S in FIG. 16.

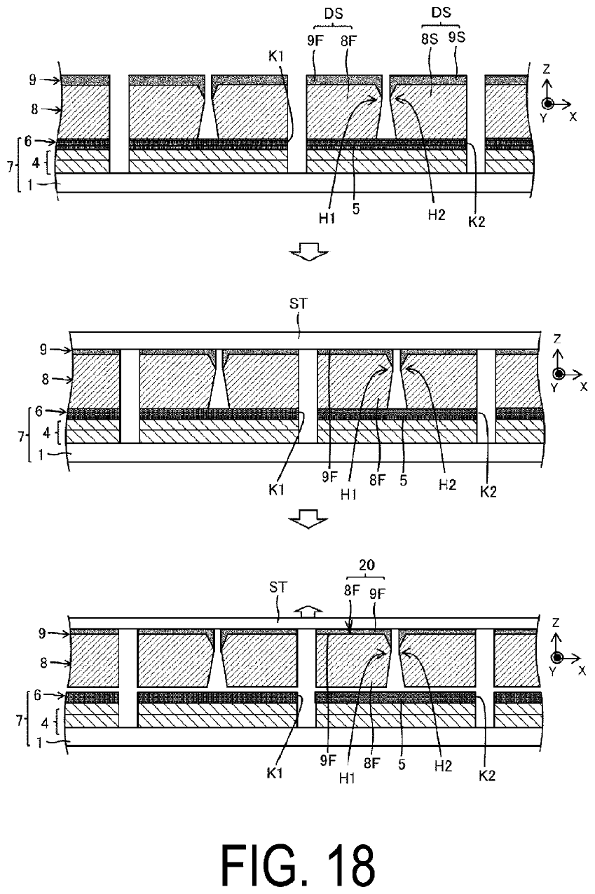

FIG. 18 is a cross-sectional view illustrating another step of separation of the element portion in Example 1. Since the ELO semiconductor layer 8 and the mask portion 5 in FIG. 17 are bonded to each other by van der Waals force (weak force), by pulling up the function layer 9 with the attractive force (adhesive force, suction force, electrostatic force, or the like) of a stamp device ST or the like, the element portion DS may be easily peeled off from the template substrate to obtain the semiconductor device 20, as illustrated in FIG. 18. Direct peeling from the mask portion 5 can be carried out using a viscoelastic elastomer stamp, an electrostatic adhesion stamp, or the like, which brings a large advantage in terms of cost, throughput, and the like. After the viscoelastic elastomer stamp, the electrostatic adhesion stamp or the like is brought into contact with the ELO semiconductor layer 8, for example, vibrations by ultrasonic waves may be applied. With the vibrations or the like, the ELO semiconductor layer 8 may be more easily peeled off from the mask portion 5.

### Example 2

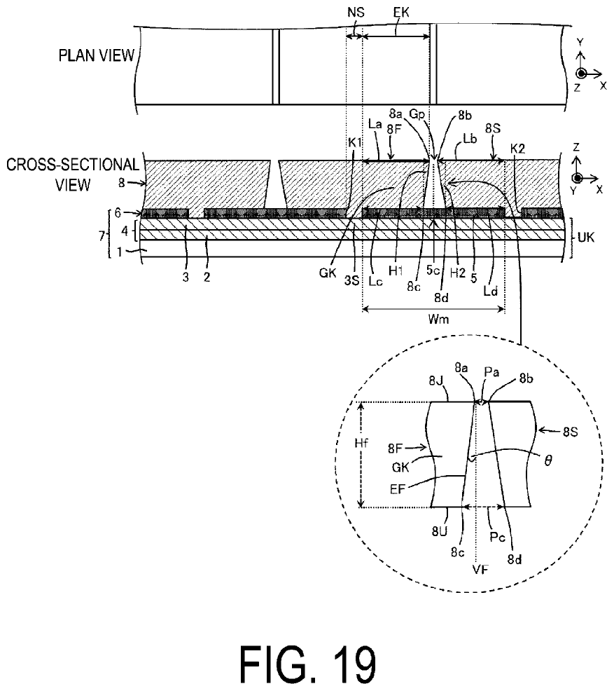

FIG. 19 is a cross-sectional view illustrating a configuration of a semiconductor substrate of Example 2. In the semiconductor substrate 10 in FIG. 19, the first semiconductor part 8F has a first upper edge 8a located between the mask-portion center 5c and the first opening portion K1 in a plan view, a first lower edge 8c (located on the mask portion 5) located between the mask-portion center 5c and the first opening portion K1 in a plan view, and a first protruding portion H1 protruding in the X direction (toward the second semiconductor part 8S side) farther than the first lower edge 8c in a plan view.

The second semiconductor part 8S has a second upper edge 8b located between the mask-portion center 5c and the second opening portion K2 in a plan view, a second lower edge 8d (located on the mask portion 5) located between the mask-portion center 5c and the second opening portion K2 in a plan view, and a second protruding portion H2 protruding in the X direction (toward the first semiconductor part 8F side) farther than the second lower edge 8d in a plan view.

Portions of the first and second semiconductor parts 8F and 8S, which overlap the mask portion 5 in a plan view, are a GaN-based crystal body GK including a GaN-based semiconductor and having an upper surface 8J and a lower surface 8U parallel to the (0001) plane (c-plane). The GaN-based crystal body GK has a non-threading dislocation density in a cross section parallel to the <0001> direction larger than a threading dislocation density in the upper surface 8J, and includes the lower edge 8c parallel to the <1-100> direction and the protruding portion (overhang portion) H1 protruding in the <11-20> direction farther than the lower edge.

In the semiconductor substrate 10 in FIG. 18, the first upper edge 8a is a top portion of the first protruding portion H1, and the second upper edge 8b is a top portion of the second protruding portion H2. In the X direction, a distance La between the first opening portion K1 and the first upper edge 8a is larger than a distance Lc between the first opening portion K1 and the first lower edge 8c, and a distance Lb between the second opening portion K2 and the second upper edge 8b is larger than a distance Ld between the second opening portion K2 and the second lower edge 8d. A gap space (gap) Gp between the first semiconductor part 8F and the second semiconductor part 8S has an inversely tapered shape in which a width of the gap space becomes wider on the mask portion 5 side.

In FIG. 19, an upper interval Pa indicating the interval between the first upper edge 8a and the second upper edge 8b is smaller than 5 μm. The ratio of the upper Interval Pa to the width Wm of the mask portion is less than 0.5, and the ratio of a lower interval Pc, which indicates the interval between the first lower edge 8c and the second lower edge 8d, to the width Wm of the mask portion is less than 0.7. An acute angle θ formed by a plane EF including the first upper edge 8a and the first lower edge 8c and a plane VF perpendicular to the X direction is 15° or less.

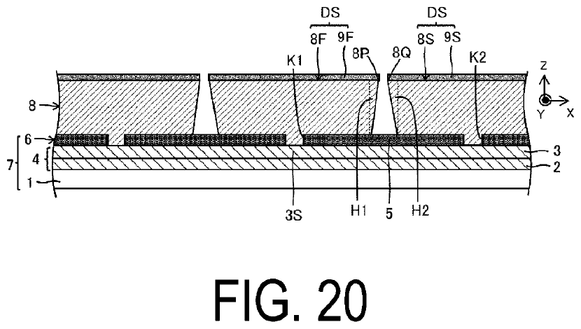

FIG. 20 is a cross-sectional view illustrating another configuration of the semiconductor substrate according to Example 2. In FIG. 20, the first function layer 9F is arranged on the first semiconductor part 8F, and the second function layer 9S is arranged on the second semiconductor part 8S.

In FIG. 20 as well, since it is difficult for the first function layer 9F formed in a layer above the first semiconductor part 8F to be formed below the top portion 8P of the first protruding portion H1, and it is difficult for the second function layer 9S formed in a layer above the second semiconductor part 8S to be formed below the top portion 8Q of the second protruding portion H2, the first and second function layers 9F and 9S are isolated from each other. This improves the yield for the step of isolating the element portion DS.

In the case where, for example, a GaN-based p-type semiconductor layer is formed in the function layer 9, since in the rise of the n-type dopant such as silicon is considerably reduced by the first and second protruding portions H1 and H2, it is difficult for the n-type dopant to be taken into the p-type semiconductor layer, and therefore, the function of the p-type semiconductor layer can be enhanced.

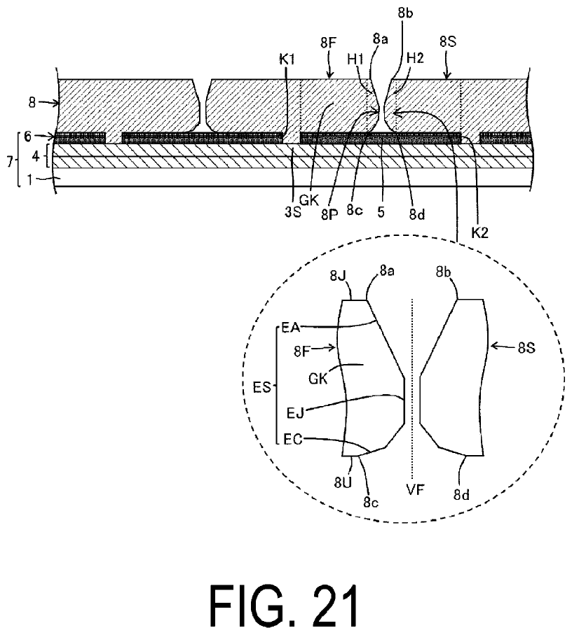

FIG. 21 is a cross-sectional view illustrating another configuration of the semiconductor substrate of Example 2. In the semiconductor substrate 10 in FIG. 21, the first semiconductor part 8F has a first upper edge 8a located between the mask-portion center 5c and the first opening portion K1 in a plan view, a first lower edge 8c (located on the mask portion 5) located between the mask-portion center 5c and the first opening portion K1 in a plan view, and a first protruding portion H1 protruding in the X direction (toward the second semiconductor part 8S side) farther than the first lower edge 8c in a plan view.

The second semiconductor part 8S has a second upper edge 8b located between the mask-portion center 5c and the second opening portion K2 in a plan view, a second lower edge 8d (located on the mask portion 5) located between the mask-portion center 5c and the second opening portion K2 in a plan view, and a second protruding portion H2 protruding in the X direction (toward the first semiconductor part 8F side) farther than the second lower edge 8d in a plan view.

Portions of the first and second semiconductor parts 8F and 8S, which overlap the mask portion 5 in a plan view, are a GaN-based crystal body GK including a GaN-based semiconductor and having an upper surface 8J and a lower surface 8U parallel to the (0001) plane (c-plane). The GaN-based crystal body GK has a non-threading dislocation density in a cross section parallel to the <0001> direction larger than a threading dislocation density in the upper surface 8J, and includes the lower edge 8c parallel to the <1-100> direction and the protruding portion (overhang portion) H1 protruding in the <11-20> direction farther than the lower edge.

In the semiconductor substrate 10 in FIG. 21, the side surface ES (end face) of the first semiconductor part includes an upper inclined surface EA including the first upper edge 8a, a vertical surface EJ perpendicular to the X direction, and a lower inclined surface EC including the first lower edge 8c.

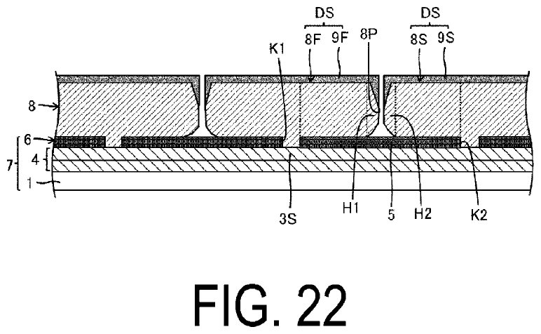

FIG. 22 is a cross-sectional view illustrating another configuration of the semiconductor substrate of Example 2. As illustrated in FIG. 22, the first and second function layers 9F and 9S may be provided on the first and second semiconductor parts 8F and 8S shown in FIG. 21.

### Example 3

In Examples 1 and 2, the ELO semiconductor layer 8 is a GaN layer, but the configuration is not limited thereto. As the ELO semiconductor layer 8 of Examples 1 to 2, an InGaN layer that is a GaN-based semiconductor layer may also be formed. The lateral film formation of the InGaN layer is carried out at a low temperature below 1000° C., for example. This is because the vapor pressure of indium increases at a high temperature and indium is not effectively taken into the film. When the film formation temperature is low, an effect is exhibited in which the interaction between the mask portion 5 and the InGaN layer is reduced. The InGaN layer has an effect of exhibiting lower reactivity with the mask portion 5 than the GaN layer. When indium is taken into the InGaN layer at an In composition level of 1% or more, the reactivity with the mask portion 5 is further lowered, which is desirable. As the gallium raw material gas, triethylgallium (TEG) is preferably used.

### Example 4

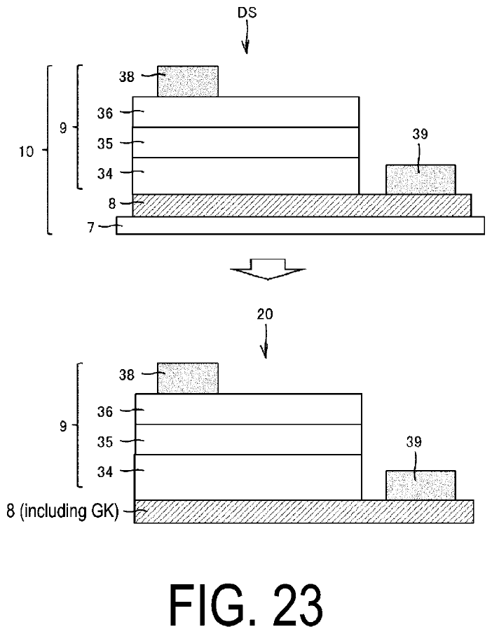

FIG. 23 is a schematic cross-sectional view illustrating a configuration of Example 4. In Example 4, the function layer 9 constituting an LED is film-formed on the ELO semiconductor layer 8. The ELO semiconductor layer 8 is an n-type layer doped with, for example, silicon. The function layer 9 includes an active layer 34, an electron blocking layer 35, and a GaN-based p-type semiconductor layer 36 in that order from the bottom layer side. The active layer 34 is a multi-quantum well (MQW), and includes an InGaN layer and a GaN layer. The electron blocking layer 35 is, for example, an AlGaN layer. The GaN-based p-type semiconductor layer 36 is, for example, a GaN layer. An anode 38 is arranged to be in contact with the GaN-based p-type semiconductor layer 36, and a cathode 39 is arranged so as to be in contact with the semiconductor layer 8. The semiconductor device 20 (including a GaN-based crystal body) can be obtained by separating the ELO semiconductor layer 8 and the function layer 9 from the template substrate 7. It is also possible to form films up to the ELO semiconductor layer 8, to take out the semiconductor substrate 10 from a film forming device once, and to form the function layer 9 in another device. In this case, an n-type GaN layer may be inserted between the ELO semiconductor layer 8 and the function layer 9, as an intermediate layer serving as a buffer during regrowth. The thickness of the intermediate layer can be from about 0.1 μm to 3 μm.

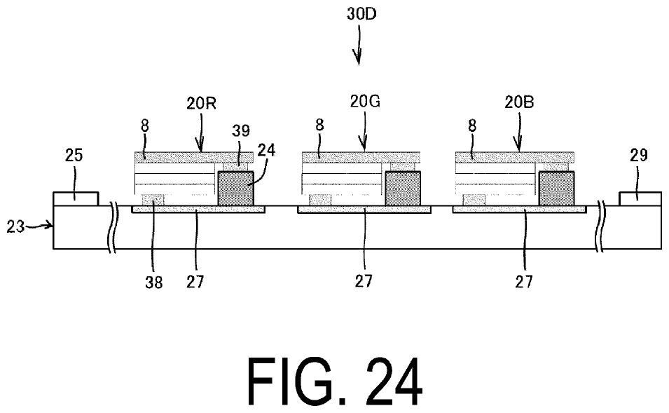

FIG. 24 is a cross-sectional view illustrating an example of application of Example 4 to an electronic device. According to Example 4, a red micro LED 20R, a green micro LED 20G, and a blue micro LED 20B may be obtained, and a micro LED display 30D (electronic device) may be constituted by mounting these LEDs on the drive substrate (TFT substrate) 23. As an example, each of the red micro LED 20R, the green micro LED 20G, and the blue micro LED 20B is mounted on a respective one of a plurality of pixel circuits 27 of the drive substrate 23 via a conductive resin 24 (for example, an anisotropic conductive resin) or the like, and then a control circuit 25, a driver circuit 29, and the like are mounted on the drive substrate 23. The drive substrate 23 may include a part of the driver circuit 29.

### Example 5

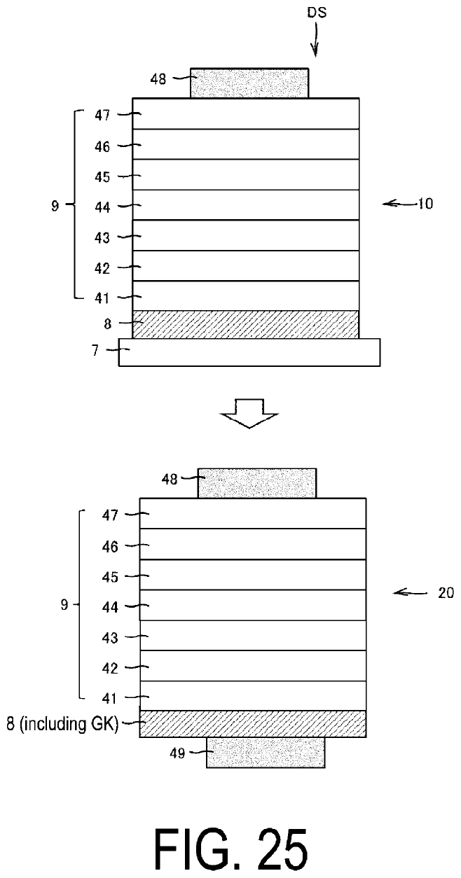

FIG. 25 is a schematic cross-sectional view illustrating a configuration of Example 5. In Example 5, the function layer 9 constituting a semiconductor laser is film-formed on the ELO semiconductor layer 8. The function layer 9 includes an n-type cladding layer 41, an n-type guide layer 42, an active layer 43, an electron blocking layer 44, a p-type guide layer 45, a p-type cladding layer 46, and a GaN-based p-type semiconductor layer 47 in that order from a lower layer side. For each of the guide layers 42 and 45, an InGaN layer may be used. A GaN layer or AlGaN layer may be used for each of the cladding layers 41 and 46. An anode 48 is arranged so as to be in contact with the GaN-based p-type semiconductor layer 47, and a cathode 49 is arranged so as to be in contact with the ELO semiconductor layer 8. The semiconductor device 20 (including a GaN-based crystal body) can be obtained by separating the ELO semiconductor layer 8 and the function layer 9 from the template substrate 7.

### Example 6

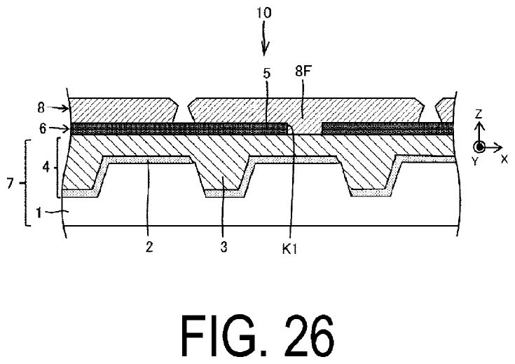

FIG. 26 is a cross-sectional view illustrating a configuration of Example 6. In Example 6, a sapphire substrate having an uneven surface is used for the main substrate 1. The underlying layer 4 includes the buffer layer 2 and the seed layer 3. In Example 6, a GaN layer having a (20-21) plane is film-formed as the underlying layer 4 on the main substrate 1. In this case, the ELO semiconductor layer 8 becomes the (20-21) plane, which is a crystal principal plane, in the underlying layer 4, and the ELO semiconductor layer 8 of a semi-polar plane may be obtained. By providing a function layer for a laser or an LED on the semipolar surface, an advantage is obtained in that the probability of recombination of electrons and holes is increased in the active layer. Note that a GaN layer having the (11-22) plane may be film-formed as the underlying layer 4 on the main substrate 1 by using a sapphire substrate having an uneven surface.

### Example 7

The underlying layer 4 need not be formed on the entire substrate. When the underlying layer 4 contains a material different from that of the main substrate 1, stress may be generated in the semiconductor substrate (ELO semiconductor layer, function layer) due to differences in thermal expansion coefficient, lattice constant, and the like. For this reason, the underlying layer 4 (at least one of the buffer layer and the seed layer) may be locally provided to overlap each opening portion of the mask pattern 6. A configuration may also be employed in which the underlying layer 4 is not provided.

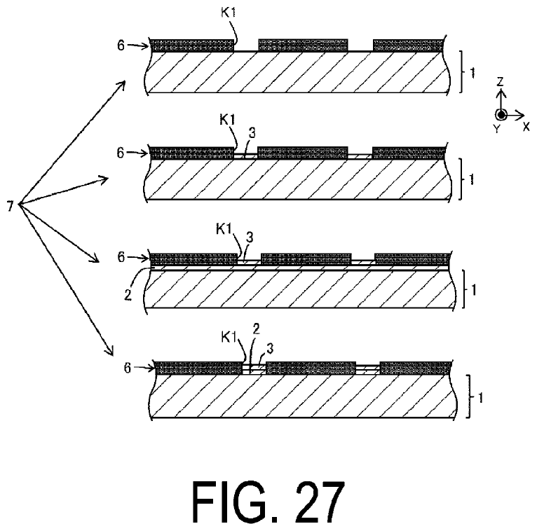

FIG. 27 is a cross-sectional view illustrating a configuration of Example 7. The template substrate (substrate for ELO growth) 7 may be formed, for example, as illustrated in FIG. 27. For example, the template substrate 7 may be constituted by the main substrate 1 and the mask pattern 6 (no underlying layer is provided), and a portion of a surface layer of the main substrate 1 overlapping the first opening portion K1 may be enabled to function as the seed portion. In this case, a GaN bulk substrate, a 6H-SiC bulk substrate, or a 4H-SiC bulk substrate may be used as the main substrate 1. The bulk substrate is a wafer (free-standing substrate) cut out from a bulk crystal body.

The template substrate 7 may be constituted by the main substrate 1, the seed layer 3 (seed portion) locally arranged so as to overlap the first opening portion K1 in a plan view, and the mask pattern 6. In this case, a configuration may be employed in which the main substrate 1 is a silicon substrate and the seed layer 3 contains AlN, or a configuration may be employed in which the main substrate 1 is a silicon carbide substrate and the seed layer 3 includes a GaN-based semiconductor.

The template substrate 7 may be constituted by the main substrate 1, the buffer layer 2 covering the main substrate 1, the seed layer 3 (seed portion) locally arranged so as to overlap the first opening portion K1 in a plan view, and the mask pattern 6. For example, a configuration may be employed in which the main substrate 1 is a silicon substrate, the buffer layer 2 includes AlN and/or SiC, and the seed layer 3 includes a GaN-based semiconductor.

The template substrate 7 may be constituted by the main substrate 1, the buffer layer 2 (buffer portion) locally arranged so as to overlap the first opening portion K1 in a plan view, the seed layer 3 (seed portion) locally arranged so as to overlap the first opening portion K1 in a plan view, and the mask pattern 6. In this case, a configuration may be employed in which the main substrate 1 is a silicon substrate, the buffer layer 2 includes AlN and/or silicon carbide, and the seed layer 3 includes a GaN-based semiconductor.

### REFERENCE SIGNS

1 Main substrate
2 Buffer layer
3 Seed layer
3S Seed portion
4 Underlying layer
5 Mask portion
6 Mask pattern
8F First semiconductor part
8B Second semiconductor part
9F First function layer
9S Second function layer
10 Semiconductor substrate
20 Semiconductor device
30 Electronic device
70 Manufacturing apparatus for manufacturing semiconductor substrate
K1 First opening portion
K2 Second opening portion
EK Low-defect portion
GK GaN-based crystal body

1. A semiconductor substrate comprising:
a template substrate including a main substrate, a first seed portion, and a second seed portion,
a first semiconductor part in contact with the first seed portion and a second semiconductor part in contact with the second seed portion, wherein
the first semiconductor part and the second semiconductor part include a nitride semiconductor and are adjacent to each other in an a-axis direction of the nitride semiconductor, and
the first semiconductor part comprises a first lower edge along an m-axis direction of the nitride semiconductor, and a first protruding portion protruding toward the second semiconductor part side farther than the first lower edge.

2. The semiconductor substrate according to claim 1, wherein
the template substrate further includes a mask pattern comprising a first opening portion and a second opening portion adjacent to each other in a first direction, and a mask portion located between the first opening portion and the second opening portion,
the first lower edge is located between a mask-portion center and the first opening portion in a plan view, and
the second semiconductor part comprises a second lower edge located between the mask-portion center and the second opening portion in a plan view, and a second protruding portion protruding toward the first semiconductor part side farther than the second lower edge in a plan view.

3. The semiconductor substrate according to claim 2, wherein
the first semiconductor part comprises a first upper edge located between the mask-portion center and the first opening portion in a plan view, and
in the first direction, a maximum distance between the first opening portion and the first protruding portion is larger than a distance between the first opening portion and the first upper edge.

4. (canceled)

5. The semiconductor substrate according to claim 3, wherein
a side surface of the first semiconductor part comprises a lower inclined surface comprising the first lower edge, and an upper inclined surface comprising the first upper edge.

6. The semiconductor substrate according to claim 5, wherein
a first acute angle formed by the lower inclined surface and a plane perpendicular to the first direction is smaller than a second acute angle formed by the upper inclined surface and a plane perpendicular to the first direction.

7. The semiconductor substrate according to claim 6, wherein
the first acute angle is 12° or less.

8-11. (canceled)

12. The semiconductor substrate according to claim 2, wherein
the first semiconductor part comprises a first upper edge located between the mask-portion center and the first opening portion in a plan view, and
the first upper edge is a top portion of the first protruding portion.

13. The semiconductor substrate according to claim 12, wherein
the second semiconductor part comprises a second upper edge located between the mask-portion center and the second opening portion in a plan view, and
the second upper edge is a top portion of the second protruding portion.

14-16. (canceled)

17. The semiconductor substrate according to claim 13, wherein
an upper interval indicating an interval between the first upper edge and the second upper edge is less than 5 μm.

18. (canceled)

19. The semiconductor substrate according to claim 13, wherein
a ratio of a lower interval, which indicates an interval between the first lower edge and the second lower edge, to a width of the mask portion is less than 0.7.

20. The semiconductor substrate according to any one of claim 13, wherein
a plane comprising the first upper edge and the first lower edge forms an angle of 12° or less with respect to a plane perpendicular to the first direction.

21. (canceled)

22. The semiconductor substrate according to claim 21, wherein
a first function layer is arranged in a layer above the first semiconductor part.

23. The semiconductor substrate according to claim 22, wherein
the first function layer comprises an active layer, and
the active layer does not extend to the first lower edge.

24. The semiconductor substrate according to claim 22, wherein
a second function layer is arranged in a layer above the second semiconductor part, and
wherein the first function layer and the second function layer are isolated from each other.

25. The semiconductor substrate according to claim 22, wherein
the first function layer comprises a GaN-based p-type semiconductor layer, and
the mask pattern comprises a silicon oxide film and/or a silicon nitride film.

26-27. (canceled)

28. The semiconductor substrate according to claim 2, wherein
the first semiconductor part comprises a low-defect portion overlapping the mask portion in a plan view, and
the low-defect portion has a threading dislocation density of 5×10⁶ [pieces/cm²] or less, and
a size of the low-defect portion in the first direction is 10 μm or larger.

29. The semiconductor substrate according to claim 2, wherein
the first semiconductor part comprises a low-defect portion overlapping the mask portion in a plan view, and
in the low-defect portion, a non-threading dislocation density in a cross section parallel to a thickness direction is larger than a threading dislocation density in an upper surface.

30. The semiconductor substrate according to claim 2, wherein
the first semiconductor part comprises a nitride semiconductor, and the main substrate is a heterogeneous substrate different from the nitride semiconductor in terms of lattice constant.

31. (canceled)

32. A GaN-based crystal body comprising a GaN-based semiconductor and having an upper surface and a lower surface parallel to a (0001) plane, the GaN-based crystal body comprising:
a lower edge parallel to a <1-100> direction, and a protruding portion protruding in a <11-20> direction farther than the lower edge, wherein
a non-threading dislocation density in a cross section parallel to a <0001> direction is larger than a threading dislocation density in the upper surface.

33-35. (canceled)

36. A manufacturing method for manufacturing the semiconductor substrate according to claim 1, the manufacturing method comprising:
growing the first and second semiconductor parts each including a group III nitride semiconductor by an ELO method at a V/III ratio of less than 1000.

37. (canceled)
